(19) United States
(12) Patent Application Publication
(10) Pub. No.: US 2025/0364788 A1
(43) Pub. Date: Nov. 27, 2025

(54) SEMICONDUCTOR LASER CHIP FOR GAS SENSOR

(71) Applicant: MIRSENSE, Palaiseau (FR)

(72) Inventors: Mathieu Carras, Palaiseau (FR); Guillaume Aoust, Palaiseau (FR); Mickael Brun, Palaiseau (FR)

(73) Assignee: MIRSENSE, Palaiseau (FR)

(21) Appl. No.: 18/873,581

(22) PCT Filed: Jul. 4, 2023
(86) PCT No.: PCT/EP2023/068437

§ 371 Date: Dec. 10, 2024

(30) Foreign Application Priority Data
Jul. 6, 2022 (FR) FR2206925

(51) Int. Cl. H01S 5/34; G01N 21/17; G01N 21/3504; H01S 5/02; H01S 5/02315; H01S 5/042

(52) U.S. Cl. CPC H01S 5/3401; G01N 21/1702; G01N 21/3504; H01S 5/0202; H01S 5/02315; H01S 5/04256; G01N 2021/1704

(57) ABSTRACT

Semiconductor laser chip (101) comprising
A substrate (105) comprising:
   two lateral faces (107),
   an lower face (109),
   an upper face (108),
at least two semiconductor lasers (102), these two lasers (102) being distributed between said two lateral faces (102) with a spacing (E) between two adjacent lasers (102),
   said substrate (101) having a width (I), this width being the distance between said two lateral faces (107) of the substrate (105), and a thickness (e), this thickness (e) being the distance measured between the lower face (109) and the upper face (108) of the substrate (105) perpendicular to the width (I), said width (I) being less than or equal to 4 times the thickness (e).

### TECHNICAL AREA

The present invention relates to the field of semiconductor lasers, and more particularly to semiconductor laser chips, especially for gas sensors.

Generally speaking, semiconductor laser chips are obtained by a complex sequence of steps involving the deposition of layers on a monocrystalline substrate (also called substrate in this description) forming a wafer, and the cutting of this wafer to obtain laser chips. This layer deposition is carried out either by liquid or gas phase epitaxy, or by molecular jetting onto the substrate. The substrate is a pure crystal (usually InP or InAs or GaAs or other semiconductor material). A laser unit is generally a parallelepipedic portion of the wafer, and is obtained by a series of chemical or physicochemical etching and deposition steps of materials that may be non- crystalline or crystalline, designed to form the laser cavity and the diffraction grating and structure the laser unit.

There are many different types of semiconductor laser chip, including Quantum Laser Cascade (QCL) chips. A quantum cascade laser chip comprises two electrodes for applying an electric field between the two electrodes, a waveguide arranged between the electrodes and a laser unit corresponding to a structure comprising a gain region formed of several layers which comprise, for example, alternating strata of a first type each defining a quantum barrier and strata of a second type each defining a quantum well, these strata being made of first and second semiconductor materials, respectively constituting the barriers and the wells. The quantum cascade laser unit also comprises two optical confinement layers arranged on either side of the gain region. The laser unit forms a rod that extends at least partially along the length of the semiconductor laser chip.

Once the laser chip has been manufactured, it is usually cleaved parallel to the bar formed by the laser units on the substrate. This fixes the width of the laser chip. It is then cleaved perpendicular to the bar to create the facets that act as mirrors. These cleavages involve breaking the substrate crystal on which the laser units have been deposited along a crystalline axis, i.e. an axis extending over the thickness of the substrate, to obtain a near-perfect mirror surface. This breaking is generally achieved by scratching the surface of the substrate containing the laser units, then applying pressure on either side of the scratch to break the crystal along this crystalline axis.

The overall production cost of a semiconductor laser chip is defined in particular by the following equation: Surface area of material used to manufacture a laser chip/Production yield of the semiconductor laser chip x Cost of manufacturing the cleaved laser chip.

It is understood that:
The surface area of material used is defined by the surface area of material (substrate and deposited layers) used to manufacture the laser chip,.
The production efficiency of the semiconductor laser chip is defined by the ratio of the number of functional laser units to the maximum number of laser units that can be produced on the laser chip,.
The cost of manufacturing the cleaved laser chip corresponds to the cost of implementing the process used to manufacture said laser chip.

Thus, the larger the surface area of the material used, and/or the lower the production yield of the semiconductor laser chip, and/or the higher the cost of manufacturing the laser chip.

In the prior art, there are laser chips comprising a single laser unit. Such semiconductor laser chips have a non-optimized production yield. This is because there is only one functional laser unit, and the surface area of the semiconductor laser chip is not exploited to the full. In other words, part of the laser chip surface is lost.

The prior art also includes semiconductor laser chips comprising a number of laser units, each configured to emit its own specific wavelength. For example, U.S. Pat. No. 7,826,509 describes a laser chip comprising several laser units typically 2 mm wide. This geometry is used in portable broadband sensors to detect a large number of chemical compounds simultaneously. The use of such a large area of material is particularly costly.

The present invention aims to reduce the overall production cost of a semiconductor laser chip by maximizing the number of laser units on the smallest laser chip obtained by cleaving.

### SUMMARY

In this description, the terms chip, laser chip and semiconductor laser chip are used interchangeably, the terms assembly and chip-baseplate assembly are used interchangeably, and the terms laser unit and semiconductor laser unit are used interchangeably.

In the present description, certain elements or parameters can be indexed, such as first unit or second unit, as well as first parameter and second parameter, or first criterion and second criterion, and so on. In this case, it's a matter of simple indexing to differentiate and name elements or parameters or criteria that are close but not identical. This indexing does not imply a priority of one element, parameter or criterion over another, and such denominations can easily be interchanged without departing from the scope of the present description. Nor does this indexing imply an order in time, for example, to assess this or that criterion.

The present invention relates to a semiconductor laser chip comprising:
A substrate, in particular a cleaved substrate, comprising:
   two lateral faces,
   a lower face,
   an upper face,.
at least two semiconductor laser units, these two laser units being distributed between said two lateral faces with a spacing between two adjacent laser units,
   said substrate having a width, this width being the distance between said two lateral faces of said substrate, and a thickness, this thickness being the distance between the lower face and the upper face of said substrate perpendicular to the width of the substrate, said width being less than or equal to 4 times the thickness of said substrate.

In one aspect of the invention, the laser chip is obtained by cleaving the substrate.

In one aspect of the invention, the two lateral faces of the substrate are obtained by cleaving said substrate, said substrate being notably cleaved.

In one aspect of the invention, the lower face and the upper face are two opposite faces of the substrate. The qualifiers lower and upper are conventions for distinguishing these two faces.

In one aspect of the invention, the two lateral faces are two opposite faces of the substrate.

By width is meant the distance between the two lateral faces of the substrate between which the semiconductor laser units are distributed with a spacing between two adjacent laser units, i.e. the laser units are arranged at different locations spaced by a spacing between two adjacent laser units in the width dimension of the substrate.

Thickness here refers to the distance between the lower face and the upper face of the substrate, with the lower face configured to rest on a baseplate and the upper face opposite the lower face.

By length, we mean the distance between two other substrate faces, each of which is joined to one of the two lateral faces, the lower face and the upper face of the substrate, and over which the laser units extend at least in part.

In particular, the presence of at least two laser units in the laser chip means that virtually the entire surface area of the laser chip can be utilized. In other words, very little surface area of the substrate, and therefore of the laser chip, is wasted. The laser units are distributed across the width of the substrate, so that a single chip comprises several laser units. This optimizes the production efficiency of the laser chip.

In one aspect of the invention, the width of the laser chip is identical to the width of the substrate.

In one aspect according to the invention, the substrate has a width less than or equal to 3.5 times the thickness of said substrate, preferably less than or equal to 3 times the thickness of said substrate, preferably less than or equal to 2.5 times the thickness of said substrate, preferably less than or equal to 2 times the thickness of said substrate, preferably less than or equal to 1.5 times the thickness.

In this way, the surface area of material used to produce the laser chip is reduced, leading to a reduction in the production cost of the laser chip, and the width of the substrate of the semiconductor laser chip is sufficiently high to prevent said laser chip from being damaged during the cleaving step, which can cause the chip to break. This substrate width/thickness ratio therefore gives said laser chip sufficient mechanical strength to avoid breakage during the cleaving step. This results in the smallest cleavable laser chip.

In one aspect according to the invention, the substrate width is between 150 μm and 1 mm, preferably between 150 μm and 750 μm, more preferably between 150 μm and 500 μm, more preferably between 150 μm and 400 μm, more preferably between 150 μm and 350 μm, more preferably between 150 μm and 300 μm, more preferably between 150 μm and 250 μm, more preferably between 200 μm and 250 μm, more preferably equal to 250 μm.

In one aspect according to the invention, the substrate thickness is between 50 μm and 350 μm, preferably between 75 μm and 300 μm, more preferably between 100 um and 200 μm, more preferably between 100 μm and 150 μm, more preferably between 120 μm and 150 μm.

In one aspect of the invention, the substrate length is between 0.5 mm and 5 mm, preferably between 1 mm and 3.5 mm, more preferably between 2 mm and 3 mm.

In one aspect of the invention, the laser chip comprises at least three laser units, these three laser units being distributed between the two lateral faces of the substrate with a spacing between two neighboring laser units. In other words, the at least three laser units are distributed across the width of the substrate. In other words, the at least three laser units are distributed across the width of the laser chip.

In one aspect of the invention, the laser units are arranged on one side of the substrate.

In one aspect of the invention, the laser units are arranged on the lower face of the substrate. In another aspect, the laser units are arranged on the upper side of the substrate.

In another aspect of the invention, the laser units are embedded in the substrate. In this aspect of the invention, the laser chip includes at least one electrically insulating material layer on either side of the laser units. For example, the insulating material is semi-insulating InP (indium phosphide). The semi-insulating InP is, for instance, so-called doped InP, to which impurities such as iron are added. In this way, the laser units are electrically isolated from one another.

In one aspect of the invention, the laser units are closer to the upper face of the substrate than to the lower face of the substrate. This means either that the laser units are embedded in the substrate closer to the upper face than to the lower face of said substrate, or that the laser units are positioned on the upper face of said laser chip substrate.

In one aspect of the invention, the laser units are closer to the lower face of the substrate than to the upper face of said substrate. This means either that the laser units are embedded in the substrate closer to the lower face than to the upper face of said substrate, or that the laser units are positioned on the lower face of the substrate.

In one aspect of the invention, the laser chip comprises at least two electrodes of different polarity configured to allow an electric current to flow through at least one laser unit of the laser chip. Said at least two electrodes are configured to be in electrical contact with said at least one laser unit.

In one aspect of the invention, the laser chip comprises at least one electrode of positive polarity and at least one electrode of negative polarity, said electrodes being configured to be in electrical contact with at least one laser unit so as to allow an electrical current to flow through said at least one laser unit.

In one aspect of the invention, at least one electrode of a given polarity is arranged on at least one laser unit.

In one aspect of the invention, the laser chip comprises as many positive polarity electrodes as it has laser units. In other words, each positive electrode is in electrical contact with a separate laser unit. For example, the laser chip comprises one laser unit and one positive polarity electrode, or the chip comprises two laser units and two positive polarity electrodes, or the chip comprises three laser units and three positive polarity electrodes, or the chip comprises N laser units and N positive polarity electrodes.

In one aspect of the invention, the laser chip comprises as many negative polarity electrodes as it has laser units. In other words, each negative electrode is in electrical contact with a separate laser unit. For example, the laser chip comprises one laser unit and one negative polarity electrode, or the chip comprises two laser units and two negative polarity electrodes, or the chip comprises three laser units and three negative polarity electrodes, or the chip comprises N laser units and N negative polarity electrodes.

In one aspect of the invention of the invention, the laser chip comprises a positive polarity electrode configured to be in electrical contact with all laser units at once.

In one aspect of the invention of the invention, the laser chip comprises a negative polarity electrode configured to be in electrical contact with all laser units at once.

In one aspect of the invention, at least one electrode is arranged on the lower face of the substrate.

In one aspect of the invention, all electrodes of the same polarity are arranged on the same side of the substrate.

In one aspect of the invention, the electrodes are configured to be electrically connected to a baseplate, in particular to electrical tracks of a baseplate.

In one aspect according to the invention, the spacing between two adjacent laser units distributed between the two lateral faces of the substrate is between 10 μm and 150 μm, preferably between 20 μm and 150 μm, more preferably between 30 μm and 150 μm, more preferably between 40 μm and 150 μm, more preferably between 50 μm and 150 μm, more preferably between 75 μm and 125 μm, more preferably equal to 100 μm. In other words, across the width of the chip, the spacing between two adjacent laser units is between 75 and 150 μm, preferably between 75 μm and 125 μm, more preferably equal to 100 μm. In this way, the spacing between two adjacent laser units is configured so that electrodes on the same side are not electrically connected to each other.

In one aspect of the invention, the spacing between two adjacent laser units distributed between the two lateral faces of the substrate is constant. In other words, when the laser chip comprises N laser units, N being greater than or equal to two, the spacing between a first laser unit and a second laser unit across the width of the substrate is the same as the spacing between said second laser unit and a third laser unit, which is the same as the spacing between the N-1st laser unit and the Nth laser unit.

In one aspect of the invention, the spacing between at least two adjacent laser units distributed between the two lateral faces of the substrate varies. In other words, the spacing between a first laser unit and a second laser unit across the width of the substrate is different from the spacing between said second laser unit and a third laser unit.

In one aspect of the invention, the electrodes are formed by depositing an electrically conductive material on the substrate, in particular a metallic material, configured to be in electrical contact with at least one laser unit. For example, said electrically conductive metallic material is chosen from gold, copper, silver or aluminum.

In one aspect of the invention, the substrate comprises at least one semiconductor material of the InP (indium phosphide) or GaAs (gallium arsenide) or GaSb (gallium antimonide) or InAs (indium arsenide) or silicon type.

In one aspect of the invention, the laser chip comprises at least one electrically insulating layer, said electrically insulating layer being configured to electrically isolate laser units arranged on the same face of the substrate from one another. In this way, the laser units each have their own electrical current flowing through them.

In one aspect of the invention, the electrically insulating layer is obtained by depositing an electrically insulating material on the substrate. For example, the electrically insulating material is chosen from silicone or rubber.

In one aspect of the invention, the electrically insulating layer is arranged between the top surface of the substrate and at least one electrode arranged on said top surface.

In one aspect of the invention, the laser chip comprises at least one wall between two electrodes, said wall being covered by said electrically insulating layer. The wall helps to flatten the surface of the laser chip, particularly when the laser units are on the upper or lower face of the substrate.

In one aspect of the invention, the laser chip is a quantum cascade laser chip. In other words, the at least two laser units are quantum cascade laser units.

In one aspect of the invention, the laser units are configured to emit light radiation in pulsed mode. In particular, this reduces the energy required to power the laser units compared with continuous operation. The efficiency of laser units (optical energy/electrical energy required) is therefore improved.

In one aspect of the invention, at least one laser unit is configured to emit light radiation at a wavelength in the infrared, preferably in the mid-infrared.

In one aspect of the invention, at least one laser unit is configured to emit light radiation in a wavelength range between 3 and 15 microns, preferably between 4 and 10 microns.

In one aspect of the invention, all the laser units on the laser chip are configured to emit light radiation at the same wavelength.

In one aspect of the invention, at least two laser units of the laser chip are configured to emit light radiation at different wavelengths.

In one aspect of the invention, the laser chip comprises N laser units, N being greater than or equal to two, at least one of said laser units being configured to have a sufficiently low electric current flowing through it to enable heat to be generated without emitting light radiation, and at least one other laser unit being configured to have a sufficiently high electric current flowing through it to generate light radiation.

In one aspect of the invention, the laser chip comprises at least N laser units, N being greater than or equal to two, at least two laser units being configured to emit light radiation at a given wavelength under different atmospheric conditions, notably at different temperatures.

In one aspect of the invention, the laser chip is configured to operate only the laser unit(s) emitting light radiation at the given wavelength at the surrounding atmospheric conditions, in particular the surrounding temperature.

The invention also relates to a chip-base assembly comprising:
At least one semiconductor laser chip as described above,
A baseplate on which said laser chip is mounted.

In other words, the chip/baseplate assembly comprises a laser chip as described above, said chip being arranged on the baseplate. In other words, the laser chip and the baseplate are superimposed.

In one aspect of the invention, the lower face of the laser chip substrate faces the baseplate. In other words, the lower face of the laser chip substrate is arranged on the baseplate and the upper face of the substrate is opposite the baseplate.

In one aspect of the invention, the electrode arranged on the lower face of the substrate is arranged on the baseplate.

In one aspect of the invention, the laser chip is fixed to the baseplate, for example by welding or bonding.

In one aspect of the invention, the baseplate comprises at least one base comprising a material with heat dissipation properties selected from copper and AlN.

In one aspect of the invention, the baseplate comprises a thermal management element, in particular a Pelletier element.

The baseplate has in particular a function of thermal management of the laser chip. It indeed allows good heat dissipation.

In one aspect of the invention, the base of the baseplate is parallelepipedal.

In one aspect of the invention, the base of the baseplate comprises a upper face, a lower face and two lateral faces, the upper face being opposite the lower face. The qualifiers lower and upper are conventions for distinguishing these two faces.

In one aspect of the invention, the laser units of the laser chip are closer to the lower face of the laser chip substrate, and therefore closer to the baseplate than to the upper side of the laser chip substrate.

In one aspect of the invention, the laser units of the laser chip are closer to the upper side of the laser chip substrate than to the lower side of the laser chip substrate, and thus to the baseplate.

In one aspect of the invention, the baseplate comprises at least two electrical tracks of different polarity, each of the electrical tracks being configured to be in electrical contact with at least one electrode of the same polarity on the laser chip.

In one aspect of the invention, the electrical tracks are configured to be in electrical contact with at least one laser unit.

In one aspect of the invention, said at least one laser unit is configured to be in electrical contact with at least two electrodes of the laser chip, said electrodes being electrically connected to the electrical tracks. In this way, the laser units are configured to be in electrical contact with the baseplate, more particularly with said electrical tracks of the baseplate.

In one aspect of the invention, the baseplate comprises as many electrical tracks of a given polarity as the laser chip comprises electrodes of the same polarity. In other words, the baseplate comprises as many electrical tracks of positive polarity as the laser chip comprises electrodes of positive polarity, and the baseplate comprises as many electrical tracks of negative polarity as the chip comprises electrodes of negative polarity.

In one aspect of the invention, the baseplate comprises a positive-polarity electrical track configured to make electrical contact with all the positive-polarity electrodes on the laser chip.

In one aspect of the invention, the baseplate comprises a negative-polarity electrical track configured to make electrical contact with all the negative-polarity electrodes on the laser chip.

In one aspect of the invention, each of the electrical tracks is arranged on the base of the baseplate.

In one aspect of the invention, each of the electrical tracks is arranged on the same face of the base of the baseplate, in particular on the upper face of said base.

In one aspect of the invention, the electrical tracks are formed by depositing an electrically conductive material, in particular a metallic deposit, on the base.

In one aspect of the invention, the chip-baseplate assembly comprises at least one electrical connector configured to electrically connect an electrical lead of the baseplate to at least one electrode of the chip. Said electrical connector is, for example, a wire or plate comprising an electrically conductive material, notably gold, copper, aluminum or silver.

In one aspect of the invention, the electrical connector is connected, on the one hand, to at least one electrode of a given polarity on the laser chip by means of an electrical contact zone, in particular by soldering or bonding, and, on the other hand, to at least one electrical track on the baseplate of the same polarity as said electrode. The electrical contact zone comprises, for example, an electrically conductive material such as gold, copper, aluminum or silver.

In one aspect of the invention, the electrical contact zone at least partially covers the laser chip electrode.

In one aspect according to the invention, the electrical contact zone has a diameter less than or equal to 100 μm, preferably less than or equal to 90 μm, preferably less than or equal to 80 μm, preferably less than or equal to 70 μm, preferably less than or equal to 60 μm, preferably less than or equal to 60 μm, preferably less than or equal to 50 μm, preferably less than or equal to 25 μm, preferably less than or equal to 10 μm.

In one aspect of the invention, an electrical track is configured to be in electrical contact with at least one electrode via a junction zone. By junction zone, we mean a junction zone in which contact between the electrical track and the electrode is physical. In other words, the electrode and the electrical track are superimposed on one another. In this case, it is not necessary to use an electrical connector for the at least one electrode and the electrical track to be in electrical contact.

In one aspect of the invention, the laser chip comprises N laser units, N being greater than or equal to two, N-1 at most of said laser units being electrically connected with the electrical tracks of the baseplate. In other words, at least one laser unit is not electrically connected to the electrical tracks of the baseplate. In this way, only the most efficient laser units are in electrical contact with the baseplate.

In one aspect of the invention, the laser chip comprises N laser units, N being greater than or equal to two, at least one of said N laser units being configured to have a sufficiently low electric current flowing through it to enable heat to be generated without emitting light radiation, and at least one other laser unit being configured to have a sufficiently high electric current flowing through it to generate light radiation.

In one aspect of the invention, the chip comprises N laser units, N being greater than or equal to two, at least one of said laser units being configured to emit light radiation at a different wavelength from the other laser units.

In one aspect of the invention, the chip-baseplate assembly comprises at least two chips as described above.

In one aspect of the invention, the chip-baseplate assembly comprises at least one laser chip comprising N laser units, N being greater than or equal to two, at least one of said laser units being configured to have a sufficiently low electric current flowing through it to enable heat to be generated without emitting light radiation, and at least one other laser unit being configured to have a sufficiently high electric current flowing through it to generate light radiation.

In one aspect of the invention, the chip-baseplate assembly comprises at least one laser chip comprising at least N laser units, N being greater than or equal to two, at least two laser units being configured to emit light radiation at a given wavelength under different atmospheric conditions, notably at different temperatures.

In one aspect of the invention, the chip-baseplate assembly is configured to operate only the laser unit(s) emitting light radiation at the wavelength given the surrounding atmospheric conditions, in particular the surrounding temperature. In this way, the chip-baseplate assembly operates the laser unit best suited to the atmospheric conditions, such as temperature.

The present invention also relates to a gas sensor comprising:
A cell forming resonator comprising a gas inlet duct, a gas outlet duct and at least one laser inlet opening,.
At least one chip-baseplate assembly as described above comprising at least two laser units, at least one of said two laser units being configured to emit, into the cell, light radiation having a wavelength whose value is specifically adapted to the excitation of a gas to be detected, so that an interaction between the light radiation and the gas to be detected contained in the cell induces the generation of a signal characteristic of the presence of said gas at a resonant frequency of the cell, and
A signal detection device.

In one aspect according to the invention, the gas sensor comprises:
A cell forming an optical resonator, comprising a gas inlet duct, a gas outlet duct and at least one aperture called laser inlet,.
At least one chip-baseplate assembly as described above comprising at least two laser units, at least one of said two laser units being configured to emit, into the cell, light radiation having a wavelength whose value is specifically adapted to the excitation of a gas to be detected, so that an interaction between the light radiation and the gas to be detected contained in the cell induces the generation of an optical signal characteristic of the presence of said gas at a resonant frequency of the cell, and
A signal detection device.

In one aspect of the invention, the gas sensor comprises a focusing or collimating device, in particular a lens configured to collimate or focus light radiation from said at least one laser unit.

In another embodiment according to the invention, the gas sensor according to the invention is a photo-acoustic gas sensor which includes the features described in FR3084745.

In this embodiment, the gas sensor comprises:
A cell forming an acoustic resonator, comprising a gas inlet duct, a gas outlet duct and at least one opening called a laser inlet;
At least one chip-baseplate assembly as described above comprising at least two laser units, at least one of said two laser units being configured to emit, into the cell, light radiation having a wavelength whose value is specifically adapted to the excitation of a gas to be detected, so that an interaction between the light radiation and the gas to be detected contained in the cell induces the generation of acoustic waves at a resonant frequency of the cell; and.
At least one detection microphone arranged in a chimney opening into the cell.

In another aspect of the invention, the chip-baseplate assembly is placed directly in front of the cell's laser input, without the interposition of focusing or collimating optical elements.

In one aspect of the invention, the chip-baseplate assembly is arranged inside the sensor cell.

In another aspect of the invention, the photoacoustic gas sensor comprises a focusing or collimating device, in particular a lens configured to collimate or focus light radiation from said at least one laser unit.

In one aspect of the invention, the sensor comprises a power supply circuit configured to operate the laser source in pulse mode. In particular, this makes it possible to reduce the power consumption of said sensor for operation compared with operation in continuous mode. The laser efficiency corresponding to the optical energy/electrical energy ratio is thus improved.

In one aspect of the invention, the gas sensor has a total length of less than 5 cm and a total width of less than 4 cm.

In one aspect of the invention, the cell is of the dual Helmholtz resonator type, comprising two first cavities connected to the detection microphone and each having a laser input, and two other cavities connected to the first cavities, comprising the gas inlet duct and the gas outlet duct.

In one aspect of the invention, the cylindrical cavities of the cell have a diameter of less than 2 mm.

In one aspect of the invention, the cell walls have an optical reflectance greater than 50%, preferably 75%.

In one aspect of the invention, the gas sensor comprises a chip-baseplate assembly comprising at least N laser units, N being greater than or equal to two, at least two laser units being configured to emit light radiation at a given wavelength under different atmospheric conditions, notably at different temperatures.

In one aspect of the invention, the sensor is configured to operate only the laser unit(s) emitting light radiation at the wavelength given the surrounding atmospheric conditions, in particular the surrounding temperature. In this way, the sensor operates the laser unit best suited to the atmospheric conditions, such as temperature.

In one aspect according to the invention, the sensor comprises a chip-baseplate assembly comprising at least N laser units, N being greater than or equal to two, at least two laser units being configured to emit light radiation at different wavelengths corresponding to different excitation wavelengths of the same gas or the same molecule of said gas, said sensor being configured to operate the at least two laser units simultaneously so as to characterize said gas under study.

In one aspect of the invention, the chip-baseplate assembly of the gas sensor comprises at least N laser units, where N is greater than or equal to two, of which at least one laser unit is configured to have a sufficiently low electric current flowing through it to generate heat without emitting light radiation, and at least one other laser unit is configured to have a sufficiently high electric current flowing through it to generate light radiation. In this way, thermal management of the gas sensor is optimized.

The invention also relates to a process for producing a chip-baseplate assembly comprising the following steps:
Laser chip formation by:
   Deposition of layers of material to form at least two laser units on a substrate, said laser units being spaced by a spacing in the width dimension of the substrate, said substrate having a thickness corresponding to the distance between a upper face and a lower face of said substrate,
   Cleavage of the substrate so as to form two lateral faces of said substrate, the width of the substrate obtained corresponding to the distance between the two lateral faces obtained, said width being less than or equal to 4 times the thickness of said substrate,
The resulting chip is attached to a baseplate.

In one aspect of the invention, the fixing step is performed either by welding or by bonding.

In one aspect of the invention, the process comprises a step of cutting a wafer, said wafer comprising the substrate and a plurality of laser units, so as to obtain the desired number of laser chips.

### BRIEF DESCRIPTION OF THE DRAWINGS

Further features, details and advantages of the invention will become apparent from the description given below by way of illustration in relation to the drawings in which:

FIG. 1 is a schematic representation of a photo-acoustic gas sensor according to the invention,

FIG. 2 is a schematic representation of a first example of a chip-baseplate assembly according to the invention,

FIG. 3 is a schematic representation of a second example of a chip-baseplate assembly according to the invention,

FIG. 4 is a schematic representation of a third example of a chip-baseplate assembly according to the invention,

FIG. 5 is a schematic representation of a fourth example of a chip-baseplate assembly according to the invention,

FIG. 6 is a schematic representation of a fifth example of a chip-baseplate assembly according to the invention,

FIG. 7 is a schematic representation of a sixth example of a chip-baseplate assembly according to the invention,

FIG. 8 is a schematic representation of a seventh embodiment of a chip- baseplate assembly according to the invention.

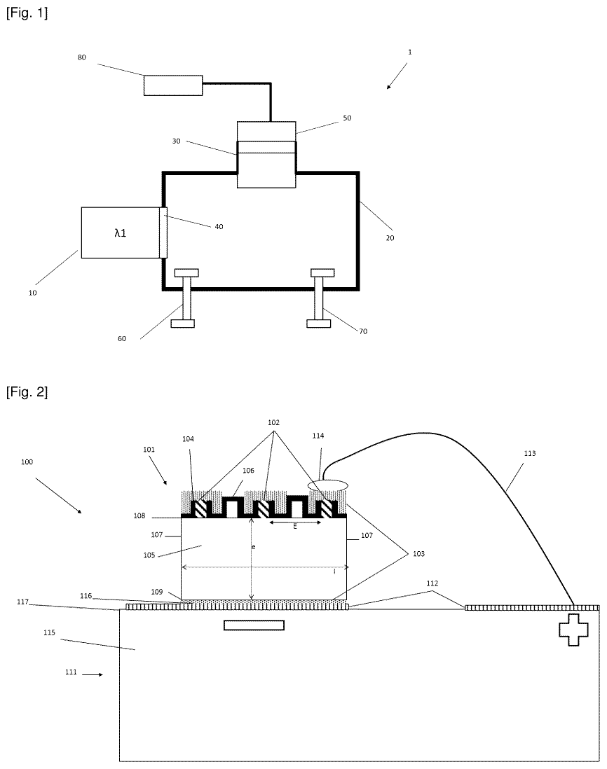

FIG. 1 illustrates a photo-acoustic gas sensor 1 according to the invention. The photo- acoustic sensor 1 according to the invention may comprise the features of the photo-acoustic sensor described in document FR3084745.

The photo-acoustic gas sensor 1 according to the invention comprises a cell 20 comprising a gas inlet duct 60 and a gas outlet duct 70, a chip-baseplate assembly 100 comprising a laser chip arranged on a baseplate, said laser chip comprising at least two laser units, at least one of which is configured to emit light radiation at a wavelength in the mid-infrared range, a chimney 30 opening into the cell comprising a detection microphone 50 and an aperture referred to as the laser inlet 40.

In the embodiment shown in FIG. 1, the chip-baseplate assembly 10 is attached to the laser input 40, so that the laser radiation emitted by the at least one laser unit of the chip-baseplate assembly 100 is emitted directly into the cell 20 without the interposition of optical focusing elements. In the embodiment shown in FIG. 1, laser radiation is produced by at least one quantum cascade laser unit (QCL) included in the chip-baseplate assembly 10, said laser unit emitting in pulsed mode at 4 to 10 microns. The QCL laser unit takes the form of a rod whose typical dimensions are 3 mm×10 μm×20 μm. The divergence of the laser beam from the laser rod is typically 60°. The 10 chip-baseplate assembly can, for example, be operated in pulsed mode at a frequency well above the cell's resonant frequency, to avoid possible interference.

The photoacoustic sensor 1 also includes an electronic detection circuit 80 connected to the detection microphone 50. In the embodiment shown in FIG. 1, the gas is introduced via an inlet duct 60 and discharged via an outlet duct 70. Both ducts are directly connected to the cell 20. During interaction between the laser emitted by the at least one laser unit of the 10 chip-baseplate assembly and the gas within cell 20, the gas is excited. Excited vibrational levels will de-excite through non-radiative transitions, resulting in molecular collisions and heating of the gas. Acoustic and thermal waves are thus generated, and the acoustic waves are detected by the detection microphone 50 placed in the chimney 30 connecting the microphone 50 to the cell 20. Microphone 50 is connected to a detection circuit 80, which determines the amplitude of the acoustic waves and thus the concentration of the gaseous species under study. As the chip-baseplate assembly 10 is placed directly in front of the input face, this design requires only basic alignment. In addition, the absence of a focusing optical element in the sensor architecture makes it much more resistant to shock and/or vibration, less sensitive to misalignment and less costly. This architecture increases the sensor's uptime and application range.

The chip-baseplate assembly 10 enables light radiation to be emitted into the cell 20 at a wavelength specifically adapted to the generation of the photo-acoustic effect in the gas to be studied.

The inner walls of gas cell 20 have an infrared-reflective optical treatment to maximize the laser flux that interacts with the gaseous atoms or molecules to be studied. For example, the cell has an optical reflection factor of over 50%, preferably over 75%.

The chip-baseplate assembly of the photoacoustic sensor 1 according to the invention can be chosen from the chip-baseplate assemblies described in FIGS. 2 to 8 of this description. The features of these chip-baseplate assemblies are described in greater detail in FIGS. 2 to 8.

FIG. 2 shows a chip-baseplate assembly 100 in a first embodiment.

In this embodiment, the chip-baseplate assembly 100 comprises a laser chip 101 and a baseplate 111 on which the laser chip 101 is placed.

Laser chip 101 comprises:
A substrate, in particular a cleaved substrate, 105 comprising:
   two lateral faces 107,
   a lower face 109,
   an upper face 108,.
Three semiconductor laser units 102 arranged on the upper face 108 of the substrate 105, said three laser units 102 being distributed between said two lateral faces 107 of the substrate 105 with a spacing E between two neighboring laser units 102.

In this example, the width I of substrate 105 is equal to the width of the laser chip.

In other words, the three laser units 2 are distributed over the width I of the substrate 105. In this way, the entire width I of the substrate, and therefore of the laser chip, is exploited. This improves the production efficiency of the laser chip 101.

The substrate 105 of the laser chip 101 has a width I less than 4 times the thickness e of said substrate. In this example, the width I of the substrate is 1.5 to 3 times greater than the thickness e, preferably 2.5 times greater than the thickness e of said substrate 105.

In this way, the surface area of material used to produce the laser chip 101 is reduced, and the production cost of the laser chip 101 is lowered. In addition, the width I/thickness e ratio of the laser chip's 105 substrate gives it the strength it needs to avoid breakage during the cleaving stage. The width I of substrate 105 is, for example, between 250 μm and 300 μm, and the thickness e of laser chip 101 is, for example, between 120 μm and 150 μm.

In this embodiment, the laser chip 101 is in an “up” configuration, i.e. the laser units 102 are closer to the upper surface 108 of the substrate 105 than to the lower surface 109 of the substrate 105. More precisely, the laser units 102 are arranged on the upper surface 108 of the substrate 105 of the laser chip 101.

The laser chip 101 comprises three electrodes 103 of positive polarity, each of these three electrodes 103 being configured to be in electrical contact with a laser unit 102. The three electrodes 103 of positive polarity are each superimposed on a laser unit 102 and are arranged on the top surface 108 of the substrate 105 of the laser chip 101. Laser chip 101 includes a negative- polarity electrode 103 configured to make electrical contact with all three laser units 102 at the same time. Here, the negative polarity electrode 103 is arranged on the lower face 109 of the substrate 105 of the laser chip 101. The electrodes 103 are formed here by deposition of an electrically conductive material, in particular a metallic material, such as gold.

The laser chip 101 comprises an electrically insulating layer 104 configured to electrically isolate the laser units 102 arranged on the same face of the substrate 105 from one another, in this case the laser units 102 arranged on the upper face 108 of the substrate 105. The electrically insulating layer 104 is formed by depositing an electrically insulating material, chosen from silicone or rubber, on the upper face 108 of the substrate 105. The electrically insulating layer 104 is arranged between the upper surface 108 of the substrate 105 and the electrodes 103 arranged on the upper surface 108 of the substrate.

The laser chip 101 comprises walls 106, said walls 106 are covered with said electrically insulating layer 104. these walls 106 are arranged between two neighboring laser units 102 so as to flatten the upper surface of the laser chip.

The spacing E between two adjacent laser units 102 is sufficiently large that electrodes 103 on the same side do not come into electrical contact with each other. The spacing E between two adjacent laser units 102 is constant, i.e. the spacing E between a first and a second laser unit 102 is the same as the spacing E between the second and a third laser unit 102. This spacing E is, for example, 100 μm. In an embodiment not shown here, the spacing E varies between two adjacent electrodes 103.

To facilitate handling, the laser chip 101 is attached to the baseplate 111. The baseplate 111 is parallelepipedic and has dimensions of 5 mm×6 mm×1.2 mm. The baseplate 111 includes a thermal management element, in particular a Pelletier element. The baseplate 111 comprises a base 115 comprising a material with heat dissipation properties, in particular AlN. Thus, the baseplate 111 also has the function of ensuring good thermal management of the laser chip 101.

The baseplate 111 comprises two electrical tracks 112 of different polarity, the two electrical tracks being arranged on an upper face 117 of the base 115. One of the electrical tracks 112 is of negative polarity, and the other electrical track 112 is of positive polarity. The positive-polarity 112 is in electrical contact with one of the positive-polarity 103 electrodes of laser chip 101, and the negative-polarity 112 is in electrical contact with the negative-polarity 103 electrode of laser chip 101. An electric field is thus created between the two electrodes 103, and an electric current flows through the laser unit 102. The electrical track 112 of positive polarity is here in electrical contact with the electrode 103 of positive polarity via an electrical connector 113 which can be a gold wire that connects said electrical track 112 and said electrode 103, said electrical connector 113 is connected with said electrode via an electrical contact zone 114, here a gold-based solder. The electrical track 112 of negative polarity is in electrical contact with the electrode 103 of negative polarity of the laser chip 101 via a junction zone 116 between said electrical track 112 and said electrode 103.

The advantage of such a design is that only the most efficient 102 laser unit is in electrical contact with the baseplate 111, i.e. the one with the best efficiency.

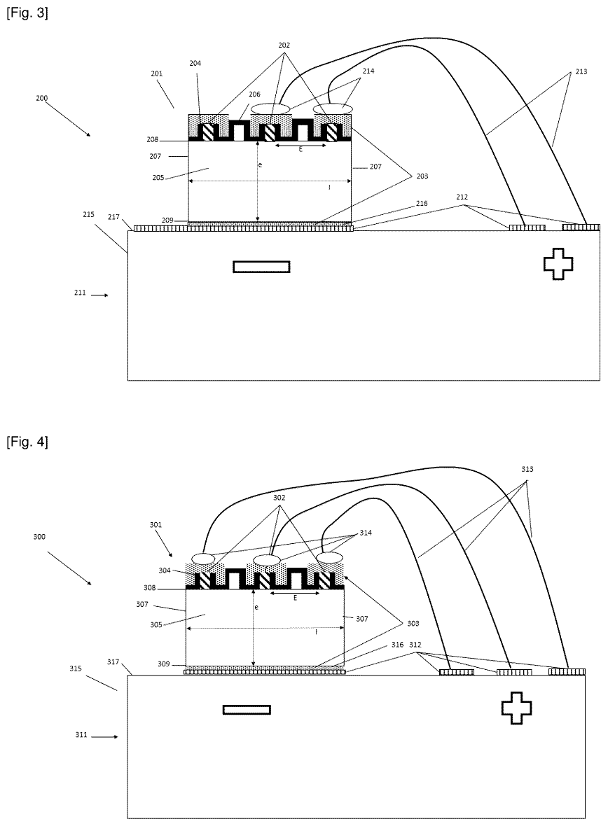

FIG. 3 shows a second example of a chip-baseplate assembly 200 according to the invention. In this embodiment, the laser chip 201 includes the same features as in the embodiment shown in FIG. 2, except that two laser units 202 are each in electrical contact with an electrode of different positive polarity 203 and with an electrode 203 of common negative polarity.

The substrate 205 of the laser chip 201 therefore has a width I less than 4 times the thickness of said substrate. In this example, the width I of the substrate is 1.5 to 3 times greater than the thickness e, preferably 2.5 times greater than the thickness e of said substrate 205.

The laser chip here comprises three laser units 202.

The baseplate 211 comprises three electrical tracks 212 of different polarity, the three electrical tracks being arranged on the upper face 217 of the base 215 of the baseplate 211. One of the electrical tracks 212 is of negative polarity, and the other two electrical tracks 212 are of positive polarity. The two electrical tracks 212 of positive polarity are in electrical contact with separate electrodes 203 of positive polarity on the laser chip 201, each of the electrodes 203 being connected to a laser unit 202. The negative-polarity electrical track 212 is in electrical contact with the negative-polarity electrode 203 of laser chip 201. Each laser unit 202 in contact with a positive electrode 203 and a negative electrode 203 thus have an electric current flowing through them.

Electrical tracks 212 of positive polarity are here in electrical contact with electrodes 203 of positive polarity via electrical connectors 213 which can be gold wires that connect said electrical tracks 212 to said electrodes 203. Said electrical connectors 213 are connected to electrodes 203 via a gold-based solder 214. The electrical track 212 of negative polarity is in electrical contact with the electrode 203 of negative polarity via a junction zone 216 between said electrical track 212 and said electrode 203.

The advantage of this type of design is that only the two best-performing laser units 202 are in electrical contact with the baseplate 211, and therefore have current flowing through them. In other words, the laser units 202 with the best optical performance are chosen.

In this example, the two laser units 202 in electrical contact with baseplate 211 can be configured to emit light radiation at the same wavelength or light radiation at different wavelengths.

Another advantage of this design is that one of the laser units 202 in electrical contact with the baseplate 211 can be configured to receive an electric current weak enough not to emit light radiation and strong enough to emit heat, while the other laser unit 202 in electrical contact with the baseplate 211 is configured to receive an electric current strong enough to emit light radiation. In this way, the heat-emitting laser unit plays a part in the thermal management of the 200 chip- baseplate assembly, thereby reducing the costs associated with the thermal management of such an assembly without causing luminous interference.

Advantageously, the laser units 202 can be configured to emit light radiation at a given wavelength under different atmospheric conditions, particularly at different temperatures. In this way, only the laser unit 202 emitting the desired wavelength under the ambient conditions can be switched on, so as not to supply the second laser unit 202 with energy unnecessarily.

FIG. 4 shows a third example of a chip-baseplate assembly 300 according to the invention. In this embodiment, the laser chip 301 comprises the same features as in the embodiment shown in FIG. 2, except that all laser units 302 are in electrical contact with a different positive polarity electrode 303 and with a common negative polarity electrode 303.

The substrate 305 of the laser chip 301 therefore has a width I less than 4 times the thickness of said substrate. In this example, the width I of the substrate is 1.5 to 3 times greater than the thickness e, preferably 2.5 times greater than the thickness e of said substrate 305.

The laser chip here comprises three 302 laser units.

The baseplate 311 comprises four electrical tracks 312 of different polarity, the four electrical tracks 312 being arranged on the upper face 317 of the base 315 of the baseplate 311. One of the 312 electrical tracks is of negative polarity, and the other three 312 electrical tracks are of positive polarity. The three electrical tracks 312 are in electrical contact with separate positive- polarity electrodes 303 on the laser chip 301, each of the positive-polarity electrodes 303 being connected to a separate laser unit 302. The negative-polarity electrical track 312 is in electrical contact with a negative-polarity electrode 303 on the laser chip 301. The laser units 302 in contact with a positive and a negative electrode 303 are thus crossed by an electric current.

Electrical tracks 312 of positive polarity are here in electrical contact with electrodes 303 of positive polarity via electrical connectors 313, which may be gold wires connecting said electrical tracks 312 to said electrodes 303. Said electrical connectors 313 are connected to electrodes 303 via a gold-based solder 314. The electrical track 312 of negative polarity is in electrical contact with the electrode 303 of negative polarity via a junction zone 316 between said electrical track 312 and said electrode 303.

In this example, the two laser units 302 in electrical contact with the baseplate 311 can be configured to emit light radiation at the same wavelength or light radiation at different wavelengths.

One advantage of this design is that one of the laser units 302 in electrical contact with the baseplate 311 can be configured to receive an electric current weak enough not to emit light radiation and strong enough to emit heat, while the other laser unit 302 in electrical contact with the baseplate 311 is configured to receive an electric current strong enough to emit light radiation. In this way, the heat-emitting laser unit 302 intervenes in the thermal management of the chip- baseplate assembly 300, thereby reducing the costs associated with the thermal management of such an assembly without causing luminous interference.

Advantageously, the laser units 302 can be configured to emit light radiation at a given wavelength under different atmospheric conditions, particularly at different temperatures. In this way, the laser unit 302 emitting the desired wavelength under the ambient conditions can be switched on only so as not to supply the second laser unit 302 with energy unnecessarily.

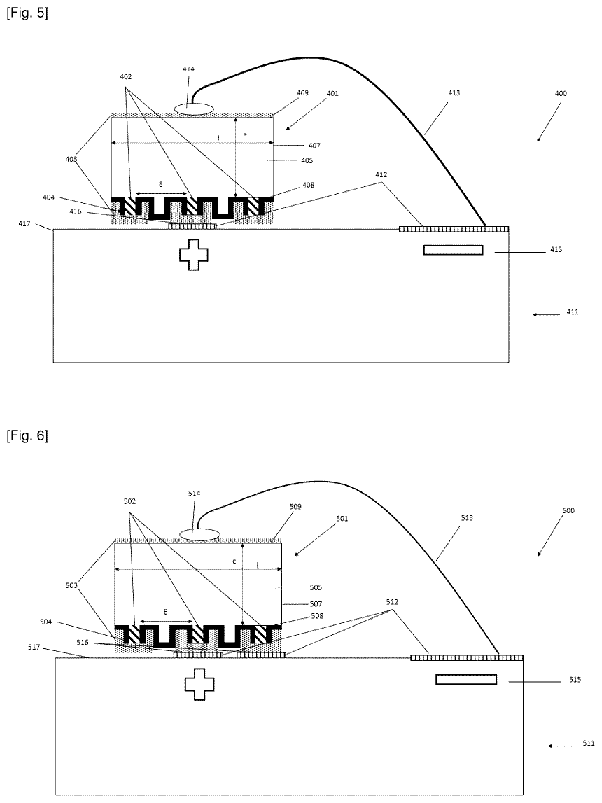

FIG. 5 shows a chip-baseplate assembly 400 in a fourth embodiment.

In this embodiment, the chip-baseplate assembly 400 includes all the features of the embodiment shown in FIG. 2, except that the chip-baseplate assembly is in the “down” position, i.e. the laser units 402 are positioned closer to the lower face 409 than to the upper face 408 of the substrate 405.

The substrate 405 of the laser chip 401 therefore has a width I less than 4 times the thickness of said substrate. In this example, the width I of the substrate is 1.5 to 3 times greater than the thickness e, preferably 2.5 times greater than the thickness e of said substrate 405.

The laser chip comprises three laser units 402.

In this example, the laser units 402 are arranged on the lower face 409 of the substrate 405.

In this example, only a positive electrode 403 of the laser chip is electrically connected to a positive electrical track 412 of the baseplate 411. Thus, only the laser unit 402 electrically connected to said positive electrode 403 on the one hand, and to a negative electrode 403 on the other, has an electric current flowing through it.

The electrical track 412 of negative polarity is here in electrical contact with the electrode 403 of negative polarity of the laser chip 401 via an electrical connector 413 which can be a gold wire that connects said electrical track 412 and said electrode 403, said electrical connector 413 is electrically connected with said electrode via a gold-based solder 414. The positive polarity electrical track 412 is in electrical contact with the positive polarity electrode via a junction zone 416 between said electrical track 412 and said electrode 403.

FIG. 6 shows a fifth example of a chip-baseplate assembly 500 according to the invention.

The substrate 505 of laser chip 501 therefore has a width I less than 4 times the thickness of said substrate. In this example, the width I of the substrate is 1.5 to 3 times greater than the thickness e, preferably 2.5 times greater than the thickness e of said substrate 505.

The laser chip comprises three laser units 502.

In this embodiment, the chip-baseplate assembly 500 includes all the features of the embodiment shown in FIG. 3, except that the chip-baseplate assembly is in the “down” position, i.e. the laser units 502 are positioned closer to the lower face 509 than to the upper face 508 of the substrate 505.

In this example, the laser units 502 are arranged on the lower face 509 of the substrate 505.

In this example, two positive polarity electrodes 503 of the laser chip 501 are each electrically connected to a positive electrical track 512 of the baseplate 511. Thus, only those laser units 502 electrically connected to said positive polarity electrodes 503 of the laser chip 501 on the one hand, and to a negative electrode 503 of the laser chip 501 on the other hand, have an electric current flowing through them.

The electrical track 512 of negative polarity is here in electrical contact with the electrode 503 of negative polarity of the laser chip 501 via an electrical connector 513 which can be a gold wire that connects said electrical track 512 and said electrode 503, said electrical connector 513 is electrically connected with said electrode via a gold-based solder 514. Electrical tracks 512 of positive polarity are in electrical contact with electrodes of positive polarity via a junction zone 516 between said electrical track 512 and said electrodes 503.

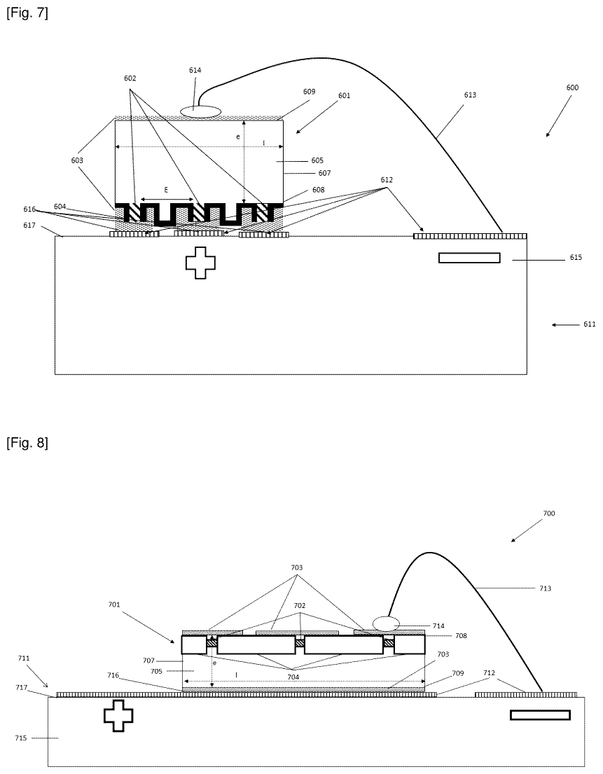

FIG. 7 shows a sixth example of a chip-baseplate assembly 600 according to the invention.

The substrate 605 of laser chip 601 therefore has a width I less than 4 times the thickness of said substrate. In this example, the width I of the substrate is 1.5 to 3 times greater than the thickness e, preferably 2.5 times greater than the thickness e of said substrate 605.

The laser chip comprises three laser units 602.

In this embodiment, the chip-baseplate assembly 600 includes all the features of the embodiment shown in FIG. 4, except that the chip-baseplate assembly is in the “down” position, i.e. the laser units 602 are positioned closer to the lower face 609 than to the upper face 608 of the substrate 605.

In this example, three positive-polarity electrodes 603 are each electrically connected to a positive electrical track 612 on baseplate 611. Thus, all laser units 602 electrically connected to said positive polarity electrodes 603 on the one hand, and to a negative electrode 603 on the other hand, have an electric current flowing through them.

The electrical track 612 of negative polarity is here in electrical contact with the electrode 603 of negative polarity via an electrical connector 613 which can be a gold wire which connects said electrical track 612 and said electrode 603, said electrical connector 613 is electrically connected with said electrode via a gold-based solder 614. The positive polarity electrical tracks 612 are in electrical contact with the positive polarity electrodes via a junction zone 616 between said electrical tracks 612 and said electrodes 603.

FIG. 8 shows a 700 chip-baseplate assembly in a seventh embodiment.

In this embodiment, the chip-baseplate assembly 700 includes all the features of the embodiment shown in FIG. 2, except that the laser units 702 are embedded in the substrate 705 of the chip 701.

The substrate 705 of laser chip 701 therefore has a width I less than 4 times the thickness of said substrate. In this example, the width I of the substrate is 1.5 to 3 times greater than the thickness e, preferably 2.5 times greater than the thickness e of said substrate 705.

The laser chip comprises three 702 laser units.

In this embodiment, the laser units 702 are closer to the top surface 708 of the substrate 705 than to the bottom surface 709 of the substrate 705.

In this embodiment, only a positive electrode 703 is electrically connected to an electrical track 712 on the baseplate. Thus, only a laser unit 702 has current flowing through it.

In another embodiment, several positive-polarity electrodes 703 could be electrically connected to positive-polarity electrical tracks 712, as shown in FIGS. 3 and 4.

In an embodiment not shown here, the laser units 702 could be embedded in the substrate 705 in such a way that they are closer to the lower face 709 of the substrate 705 than to the upper face 708 of the substrate.

In this embodiment, the substrate comprises a layer of semi-insulating material on either side of the 702 laser units, so as to electrically isolate them from one another.

The other features of the embodiments shown in FIGS. 2 to 7 apply here.

1. A semiconductor laser chip comprising:
a substrate comprising:
two lateral faces,
an lower face,
an upper face; and
at least two semiconductor lasers, these two lasers being distributed between said two lateral faces with a spacing between two adjacent lasers,
wherein said substrate having a width,
wherein the width being the distance between said two lateral faces of the substrate and a thickness,
wherein the thickness being the distance measured between the lower face and the upper face of the substrate perpendicular to the width, said width being less than or equal to 4 times the thickness.

2. The semiconductor laser chip according to claim 1, wherein the substrate has a width 1.5 to 3 times greater than the thickness.

3. The semiconductor laser chip according to claim 1, it comprises further comprising at least three laser units. these three laser units being distributed between said two lateral faces of the substrate with a spacing between two adjacent lasers.

4. The semiconductor laser chip according to claim 1, wherein the laser units are closer to the upper face of the substrate than to the lower face of the substrate.

5. The semiconductor laser chip according to claim 1, further comprising at least two electrodes of different polarity configured to allow the passage of an electric current in at least one laser unit of the laser chip.

6. The semiconductor laser chip according to claim 1, further comprising at least one insulating layer configured to electrically isolate laser units arranged on the same substrate face from one another.

7. The semiconductor laser chip according to claim 1, wherein the substrate comprises at least one semiconductor material of indium phosphide or gallium arsenide or gallium antimonide or indium arsenide or silicon type.

8. The semiconductor laser chip according to claim 1, wherein the laser chip is a quantum cascade laser chip comprising quantum cascade laser units.

9. The semiconductor laser chip according to claim 1, wherein the at least one laser unit is a quantum cascade laser unit emitting in pulsed mode at 4 to 10 microns.

10. A chip-baseplate assembly comprising:
at least one semiconductor laser chip as claimed according to claim 1; and
a baseplate on which said at least one semiconductor laser chip is mounted.

11. The chip-baseplate assembly according to claim 10, wherein the baseplate comprises;
at least two electrical tracks of different polarity,
wherein each of the electrical tracks being configured to be in electrical contact with at least one electrode of the same polarity.

12. The chip-baseplate assembly according to claim 10, wherein the at least one semiconductor laser chip comprises N laser units, N being greater than or equal to two, wherein at most N-1 of said laser units being electrically connected with electrical tracks of the baseplate.

13. The chip-baseplate assembly according to claim 10, wherein the at least one semiconductor laser chip comprising at least N laser units, N being greater than or equal to two, at least two laser units being configured to emit light radiation at a given wavelength under different atmospheric conditions, in particular at different temperatures.

14. A gas sensor comprising:
a cell forming a resonator, comprising a gas inlet duct, a gas outlet duct and at least one so-called laser inlet aperture;
at least one chip-baseplate assembly as claimed in claim 10, comprising at least two laser units, at least one of said two laser units being configured to emit, into the cell, a light radiation having a wavelength whose value is specifically adapted to the excitation of a gas to be detected, so that an interaction between the light radiation and the gas to be detected contained in the cell induces the generation of a signal characteristic of the presence of said gas at a resonance frequency of the cell; and
a signal detection device.

15. A process for producing a chip-baseplate assembly as claimed according to claim 10, comprising the following steps:
forming a semiconductor laser chip comprising:
forming at least two laser units on a substrate by a deposition of layers of material,
wherein said laser units being spaced by a spacing in the width dimension of the substrate,
wherein said substrate having a thickness corresponding to the distance between a upper face and a lower face of said substrate,
forming two lateral faces of said substrate by a cleavage of the substrate,
obtaining the width of the substrate corresponding to the distance between the two lateral faces obtained,
wherein said width being less than or equal to 4 times the thickness of said substrate; and
attaching the resulting chip to a baseplate.
